(19) United States
(12) Patent Application Publication
(10) Pub. No.: US 2018/0336932 A1
(43) Pub. Date: Nov. 22, 2018

(54) SEMICONDUCTOR DEVICE

(71) Applicant: Renesas Electronics Corporation, Tokyo (JP)

(72) Inventor: Kenji FUJITANI, Tokyo (JP)

(21) Appl. No.: 15/909,987

(22) Filed: Mar. 1, 2018

(30) Foreign Application Priority Data
May 22, 2017 (JP) 2017-100852

(51) Int. Cl. G11C 5/14; H02M 1/14

(52) U.S. Cl. CPC G11C 5/145; H02M 1/143

(57) ABSTRACT

In a semiconductor device according to related art, there is a problem that it is impossible to increase an operation speed when a power supply noise is suppressed. According to one embodiment, a semiconductor device includes a first power supply line, a second power supply line that is branched off from a branching point on the first power supply line, an internal circuit configured to receive power from the second power supply line, and a clock generation circuit configured to supply an operation clock to the internal circuit, in which, when a voltage difference between a determination threshold voltage VCC0 acquired from a position on the first power supply line that is closer to a power supply source than the branching point is and a monitor voltage VCC1 acquired from the second power supply line exceeds a predetermined voltage, the semiconductor device changes a timing of an edge of the operation clock until that the voltage difference between the monitor voltage VCC1 and the determination threshold voltage VCC0 returns to a predetermined recovery possible voltage.

### CROSS-REFERENCE TO RELATED APPLICATIONS

This application is based upon and claims the benefit of priority from Japanese patent application No. 2017-100852, filed on May 22, 2017, the disclosure of which is incorporated herein in its entirety by reference.

### BACKGROUND

The present disclosure relates to a semiconductor device, and relates to, for example, a semiconductor device including an internal circuit that operates in synchronization with an operation clock.

In recent years, in semiconductor devices, while it is required to improve the speed of an operation clock, it is also required to reduce power consumption in accordance with a reduction in size of the semiconductor devices. In order to meet this demand, an increase in the power consumption in accordance with an improvement in the operation speed has been prevented from occurring by decreasing a power supply voltage supplied to the semiconductor device. However, when the power supply voltage supplied to circuit elements is reduced, a problem that a difference between the power supply voltage that is actually supplied to the circuit elements in order to maintain the circuit operation and the power supply voltage that is supplied to the semiconductor device (power supply noise margin) becomes small occurs. One example of the reduction in the power supply noise margin and one example of the countermeasure against the decrease in the power supply noise margin are disclosed in Japanese Unexamined Patent Application Publication No. 2011-28790.

Japanese Unexamined Patent Application Publication No. 2011-28790 discloses a semiconductor storage device and a refresh control method of the semiconductor storage device. This semiconductor storage device is, for example, a Dynamic Random Access Memory (DRAM). The DRAM includes a plurality of memory units, and performs a refresh operation that amplifies data stored in a large number of memory devices by a sense amplifier at a predetermined cycle in order to prevent corruption of data stored in the memory devices provided in a plurality of memory units. Since the number of circuits that operate in the refresh operation at the same timing is larger than the number of circuits that operate in a normal reading operation at the same timing, an increase in the power consumption in accordance with the refresh operation and a decrease in the power supply voltage in accordance with the increase in the power consumption are serious problems.

In order to solve the aforementioned problems, the refresh control method disclosed in Japanese Unexamined Patent Application Publication No. 2011-28790 illustrates one method of decreasing the reduction of the power supply voltage. The semiconductor storage device disclosed in Japanese Unexamined Patent Application Publication No. 2011-28790 is a semiconductor storage device including a plurality of memory units, in which a common clock is input to the plurality of memory units, each of the memory units including a memory cell array, a control circuit configured to control an operation of the memory cell array based on the clock, and a delay circuit configured to delay the clock that has been input and output the delayed clock to the control circuit, in which, in the refresh operation of the plurality of memory units, the delay circuit of each of the memory units outputs the clock that has been input to the control circuit, the delay amount of the clock being different for each memory unit.

### SUMMARY

However, the degree of the decrease in the power supply voltage in accordance with the increase in the power consumption varies depending on the state of the plurality of internal circuits provided in the semiconductor device, such as a state of data stored in the memory unit, which is the target of a refresh operation, and it may not be necessary that the operation be delayed for each memory unit. Therefore, when the delay amount of the clock to be supplied is uniformly made different for each memory unit in accordance with the refresh operation as in the semiconductor storage device disclosed in Japanese Unexamined Patent Application Publication No. 2011-28790, there is a problem that it is difficult to improve the operation speed of the circuit.

The other problems of the related art and the novel characteristics of the present disclosure will be made apparent from the descriptions of the specification and the accompanying drawings.

According to one embodiment, a semiconductor device includes a first power supply line, a second power supply line that is branched off from a branching point on the first power supply line, an internal circuit that receives power from the second power supply line, and a clock generation circuit configured to supply an operation clock to the internal circuit, in which, when a voltage difference between a determination threshold voltage acquired from a position on the first power supply line that is closer to a power supply source than the branching point is and a monitor voltage acquired from the second power supply line exceeds a predetermined voltage, the semiconductor device changes a timing of an edge of the operation clock until that the voltage difference between the monitor voltage and the determination threshold voltage returns to a predetermined recovery possible voltage.

According to the embodiment, the semiconductor device is able to change the operation state of the internal circuit in accordance with the degree of the decrease in the power supply voltage to be supplied to the internal circuit to temporarily adjust the degree of the decrease in the power supply voltage.

### BRIEF DESCRIPTION OF THE DRAWINGS

The above and other aspects, advantages and features will be more apparent from the following description of certain embodiments taken in conjunction with the accompanying drawings, in which:

FIG. 1 is a block diagram of a semiconductor device according to a first embodiment;

FIG. 2 is a block diagram of an internal circuit according to the first embodiment;

FIG. 3 is a diagram for describing one example of a voltage difference detection circuit 11 and a voltage input to the voltage difference detection circuit 11 according to the first embodiment;

FIG. 4 is a block diagram of a clock generation circuit according to the first embodiment;

FIG. 5 is a timing chart for describing an operation of the semiconductor device according to the first embodiment;

FIG. 6 is a block diagram of a semiconductor device according to a second embodiment;

FIG. 7 is a block diagram of a voltage difference detection circuit according to the second embodiment;

FIG. 8 is a block diagram of a clock generation circuit according to the second embodiment;

FIG. 9 is a block diagram of a semiconductor device according to a third embodiment;

FIG. 10 is a block diagram of a clock generation circuit according to the third embodiment; and

FIG. 11 is a timing chart for describing an operation of the semiconductor device according to the third embodiment.

### DETAILED DESCRIPTION

For the sake of clarification of the description, the following description and the drawings are omitted and simplified as appropriate. Further, throughout the drawings, the same components are denoted by the same reference symbols and overlapping descriptions are omitted as necessary.

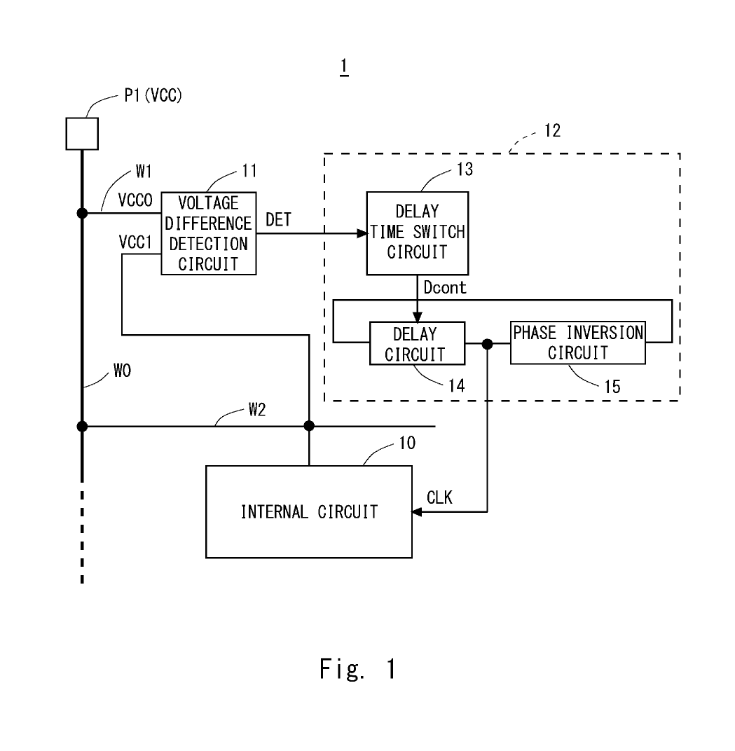

First, FIG. 1 shows a block diagram of a semiconductor device 1 according to a first embodiment. The semiconductor device 1 includes a plurality of internal circuits, each of which operates based on an operation clock. The internal circuit may be a memory unit or the like disclosed in Japanese Unexamined Patent Application Publication No. 2011-28790 as well as a charge pump circuit shown below. Further, in the internal circuit, a transistor is switched to be ON and OFF in accordance with an input of a rising edge or a falling edge of the operation clock and the power consumption in the internal circuit increases.

As shown in FIG. 1, the semiconductor device 1 according to the first embodiment includes an internal circuit 10, a voltage difference detection circuit 11, and a clock generation circuit 12. Further, the semiconductor device 1 distributes a power supply voltage supplied to a pad P1 to the whole chip using a main power supply line W0 and further distributes the power supply voltage that has been distributed to the internal circuit using a branch power supply line W2 branched off from the main power supply line W0. It is assumed that a branch power supply line W1 shown in FIG. 1 is a line that is used to monitor the voltage of the main power supply line W0 and the amount of the current that flows through the branch power supply line W1 is quite small. While the voltage difference detection circuit 11 and the clock generation circuit 12 also operate based on the power supply voltage supplied through a branch power supply line branched off from the main power supply line W0, the branch power supply line to these circuits is not shown in the drawings since an amount of a change in the power consumed in these circuits is smaller than the amount of a change in the power consumed in the internal circuit and the voltage fluctuation in this branch power supply line is small.

In the following description, the first power supply line W0 directly connected to the pad P1 in FIG. 1 is represented by the main power supply line W0. Further, the second power supply line W2 branched off from the branching point on the main power supply line W0 is represented by the branch power supply line W2. Then the voltage value acquired from a position on the main power supply line W0 closer to the power supply source (e.g., the pad P1) than the branching point at which the branch power supply line W2 is branched off from the main power supply line W0 is represented by a determination threshold voltage VCC0, and a voltage acquired from the branch power supply line W2 is represented by a monitor voltage VCC1. Further, the determination threshold voltage VCC0 is supplied to the voltage difference detection circuit 11 via the branch power supply line W1 branched off from the voltage acquisition point on the main power supply line W0.

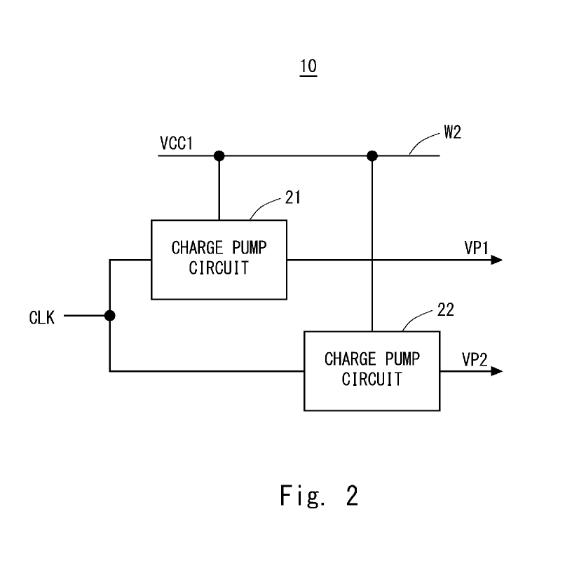

The internal circuit 10 includes a transistor whose ON and OFF are switched based on an operation clock CLK, and is operated based on this operation clock CLK. In the following description, a charge pump circuit will be explained as one example of the internal circuit 10. FIG. 2 shows a block diagram of the internal circuit 10 according to the first embodiment.

As shown in FIG. 2, the internal circuit 10 includes charge pump circuits 21 and 22. The charge pump circuits 21 and 22 boost the power supply voltage VCC1 supplied from the branch power supply line W2 to output boosted voltages VP1 and VP2. The charge pump circuits 21 and 22 switch ON and OFF of the transistor that composes the circuit based on the operation clock CLK, thereby performing an operation of accumulating charges supplied from the branch power supply line W2 in a pump capacitor and an operation of supplying the charges accumulated in the pump capacitor to an output capacitor in a repeated manner. Accordingly, when the frequency of the operation clock CLK is high, the amount of current that is consumed in the charge pump circuits 21 and 22 via the branch power supply line W2 increases, and when the frequency of the operation clock CLK is low, the amount of current that is consumed in the charge pump circuits 21 and 22 via the branch power supply line W2 decreases.

The voltage difference detection circuit 11 detects the voltage difference between the voltage VCC0 of the main power supply line W0 and the voltage VCC1 of the branch power supply line W2 and switches the logic level of a power supply fluctuation detection signal DET in accordance with this voltage difference. The power supply fluctuation detection signal DET may be switched to an enable state, which is a high level state (e.g., a power supply voltage level), and to a disable state, which is a low level state (e.g., a ground voltage level).

Specifically, the voltage difference detection circuit 11 switches the logic level of the power supply fluctuation detection signal DET based on the voltage difference between the determination threshold voltage VCC0 acquired from a position on the main power supply line W0 that is closer to the power supply source (e.g., the pad P1) than the branching point at which the branch power supply line W1 is branched off from the main power supply line W0 is and the monitor voltage VCC1 acquired from the branch power supply line W1. In the example described in the first embodiment, the voltage difference detection circuit 11 switches the power supply fluctuation detection signal DET to the enable state when the voltage difference between the determination threshold voltage VCC0 and the monitor voltage VCC1 becomes equal to or larger than a predetermined first threshold voltage VT1. Further, the voltage difference detection circuit 11 switches the power supply fluctuation detection signal DET to the disable state when the voltage difference between the determination threshold voltage VCC0 and the monitor voltage VCC1 becomes equal to or smaller than a second threshold voltage VT2 smaller than the first threshold voltage VT1.

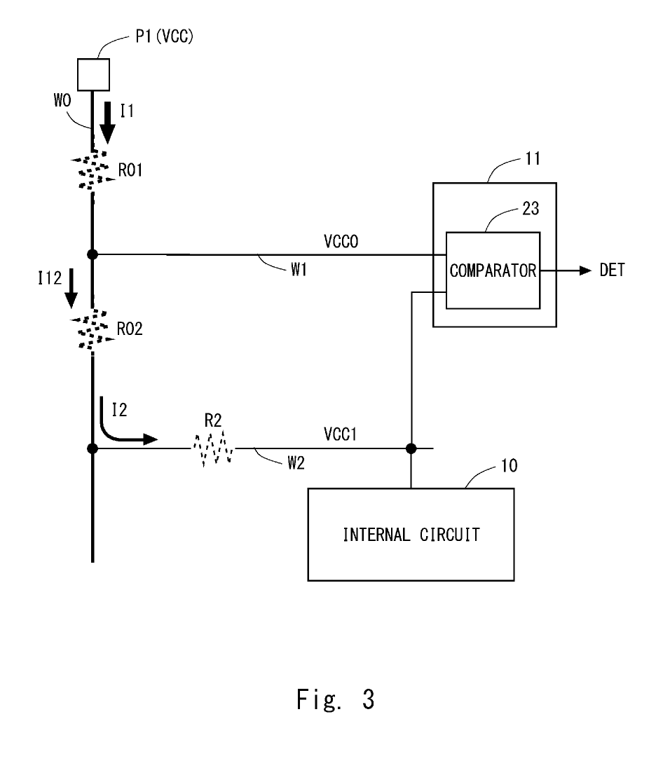

FIG. 3 shows a diagram for describing one example of the voltage difference detection circuit 11 and the voltage input to the voltage difference detection circuit 11 according to the first embodiment. As shown in FIG. 3, the main power supply line W0 includes wiring resistors R01 and R02. Then the voltage difference detection circuit 11 acquires the determination threshold voltage VCC0 by the branch power supply line W11 branched off from a position on the main power supply line W0 that is closer to the pad P1 than the branching point at which the branch power supply line W2 is branched off from the main power supply line W0 is. In the example shown in FIG. 3, the wiring resistor between the pad P1 and the branching point at which the branch power supply line W1 is branched off from the main power supply line W0 is represented by R01, and the wiring resistor between the branching point at which the branch power supply line W1 is branched off from the main power supply line W0 and the branching point at which the branch power supply line W2 is branched off from the main power supply line W0 is represented by R02. The branch power supply line W2 includes a wiring resistor R2 that is provided between the branching point at which the branch power supply line W2 is branched off from the main power supply line W0 and a connection point on the branch power supply line W2 to which the internal circuit 10 is connected. Then the voltage difference detection circuit 11 acquires the monitor voltage VCC1 from the vicinity of the connection point on the branch power supply line W2 to which the internal circuit 10 is connected. In another aspect, the voltage difference detection circuit 11 acquires the monitor voltage from the point at which a voltage decrease occurring due to the wiring resistor R2 of the branch power supply line W2 appears due to an influence of the power consumption in the internal circuit 10.

Further, as shown in FIG. 3, the determination threshold voltage VCC0 becomes smaller than the power supply voltage VCC by the amount that corresponds to the voltage generated when a current I1 flows through the parasitic resistance R01. The monitor voltage VCC1 becomes smaller than the power supply voltage VCC0 by the amount that corresponds to the voltage obtained by adding the voltage generated when a current I2 flows through the parasitic resistance R02 to the voltage generated when the current I2 flows through the parasitic resistance R2.

The voltage difference detection circuit 11 includes a comparator 23. This comparator 23 is, for example, a hysteresis converter. The comparator 23 switches the power supply fluctuation detection signal DET to the enable state when the voltage difference between the determination threshold voltage VCC0 and the monitor voltage VCC1 becomes larger than a first threshold voltage VT1. Further, after the power supply fluctuation detection signal DET is switched to the enable state, the comparator 23 maintains the power supply fluctuation detection signal DET to the enable state until that the voltage difference between the determination threshold voltage VCC0 and the monitor voltage VCC1 becomes smaller than a second threshold voltage VT2 smaller than the first threshold voltage VT1. Then the comparator 23 switches, when the voltage difference between the determination threshold voltage VCC0 and the monitor voltage VCC1 becomes equal to or smaller than the second threshold voltage VT2, the power supply fluctuation detection signal DET to the disable state. After the power supply fluctuation detection signal DET is switched to the disable state, the comparator 23 maintains the power supply fluctuation detection signal DET to the disable state until that the voltage difference between the determination threshold voltage VCC0 and the monitor voltage VCC1 becomes equal to or larger than the first threshold voltage VT1.

The clock generation circuit 12 supplies the operation clock CLK to the internal circuit 10. Further, the clock generation circuit 12 makes a timing of a rising edge or a falling edge of the operation clock CLK in the period in which the power supply fluctuation detection signal DET is in the enable state different from that in the period in which the power supply fluctuation detection signal DET is in the disable state. In the first embodiment, the clock generation circuit 12 sets the frequency of the operation clock CLK in the period in which the power supply fluctuation detection signal DET is in the enable state to be lower than the frequency of the operation clock CLK in the period in which the power supply fluctuation detection signal DET is in the disable state.

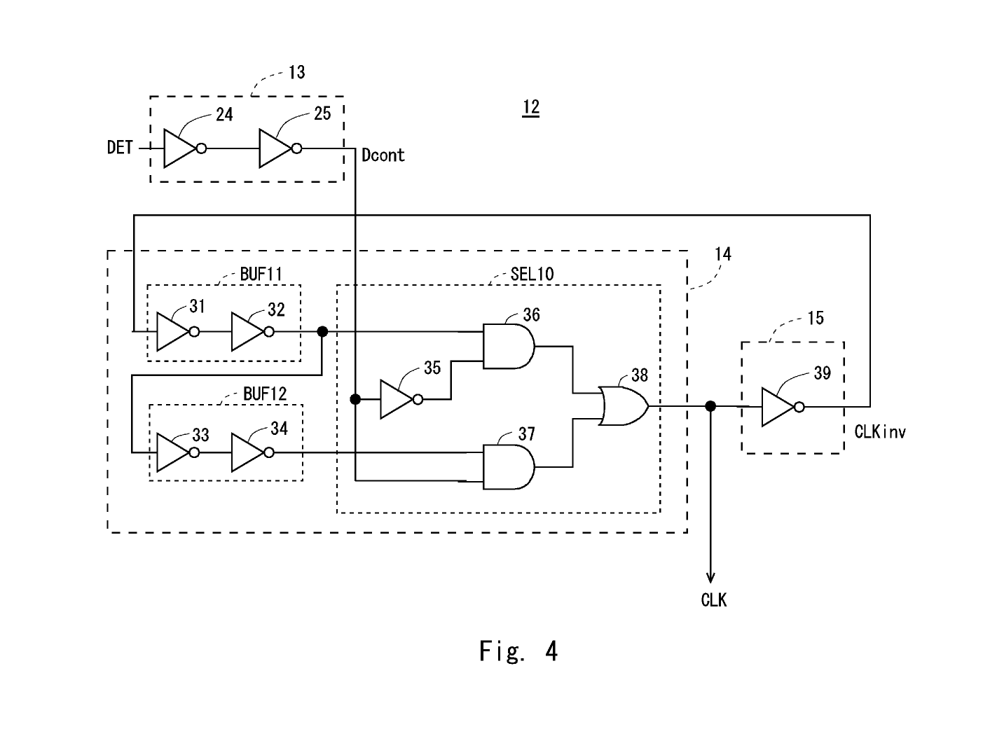

Now, one example of a circuit configuration of the clock generation circuit 12 will be explained. FIG. 4 shows a block diagram of the clock generation circuit 12 according to the first embodiment. As shown in FIG. 4, the clock generation circuit 12 includes a delay time switch circuit 13, a delay circuit 14, and a phase inversion circuit 15. The delay time switch circuit 13 receives the power supply fluctuation detection signal DET and outputs a delay amount control signal Dcont to the delay circuit 14. The delay time switch circuit 13 includes inverters 24 and 25 that are connected in series. That is, the delay time switch circuit 13 is a buffer circuit that supplies the power supply fluctuation detection signal DET to the delay circuit 14 as the delay amount control signal Dcont.

The delay circuit 14 and the phase inversion circuit 15 compose a ring oscillator by odd-numbered inverters that are connected in series in a loop manner. The delay circuit 14 increases or decreases the number of inverters included in the ring oscillator in accordance with the delay amount control signal Dcont. The delay circuit 14 increases or decreases the inverters in units of two inverters. Further, in the clock generation circuit 12, the clock signal output from the delay circuit 14 is the operation clock CLK.

The delay circuit 14 includes a first buffer circuit (e.g., a buffer circuit BUF11), a second buffer circuit (e.g., a buffer circuit BUF12), and a selection circuit SEL10. The buffer circuit BUF11 transmits an inversion operation clock CLKinv output from the phase inversion circuit 15 to a subsequent circuit by inverters 31 and 32 that are connected in series. The buffer circuit BUF12 transmits a signal output from the buffer circuit BUF11 to a subsequent circuit by inverters 33 and 34 connected in series. The selection circuit SEL10 selects, when the delay amount control signal Dcont is in the enable state, the signal output from the buffer circuit BUF12 and outputs the operation clock CLK. Further, the selection circuit SEL10 selects, when the delay amount control signal Dcont is in the disable state, the signal output from the buffer circuit BUF11 and outputs the operation clock CLK.

The selection circuit SEL10 includes an inverter 35, AND circuits 36 and 37, and an OR circuit 38. The inverter 35 outputs a signal obtained by inverting the delay amount control signal Dcont to the AND circuit 36. The AND circuit 36 transmits the output signal of the buffer circuit BUF11 to the OR circuit 38 when the delay amount control signal Dcont inverted by the inverter 35 is in the high level, that is, when the delay amount control signal Dcont is in the disable state. The AND circuit 37 transmits the output signal of the buffer circuit BUF12 to the OR circuit 38 when the delay amount control signal Dcont is in the high level, that is, when the delay amount control signal Dcont is in the enable state. The OR circuit 38 outputs a signal, which is a logical OR of the signal output from the AND circuit 36 and the signal output from the AND circuit 37, as the operation clock CLK.

The phase inversion circuit 15 includes an inverter 39. Then the inverter 39 outputs a signal obtained by inverting the operation clock CLK as the inversion operation clock CLKinv.

The ring oscillator composed of the delay circuit 14 and the phase inversion circuit 15 generates the clock signal when the number of inverters that are connected in series in a loop manner is an odd number. In general, the ring oscillator is able to reduce the frequency of the clock signal to be generated when the number of inverters that are connected in series in a loop manner is large, and is able to increase the frequency of the clock signal to be generated when the number of inverters that are connected in series in a loop manner is small. In the clock generation circuit 12 shown in FIG. 4, when the delay amount control signal Dcont is in the enable state, the number of inverters that are connected in series in a loop manner is five stages (the number of inverters included in the buffer circuits BUF11 and BUF12 and the inverter 39). Further, in the clock generation circuit 12, when the delay amount control signal Dcont is in the disable state, the number of inverters that are connected in series in a loop manner becomes three stages (the number of inverters included in the buffer circuit BUF 11 and the inverter 39). Therefore, when the delay amount control signal Dcont is switched to the enable state, the clock generation circuit 12 is able to reduce the frequency of the clock signal more than that in the case in which the delay amount control signal Dcont is switched to the disable state.

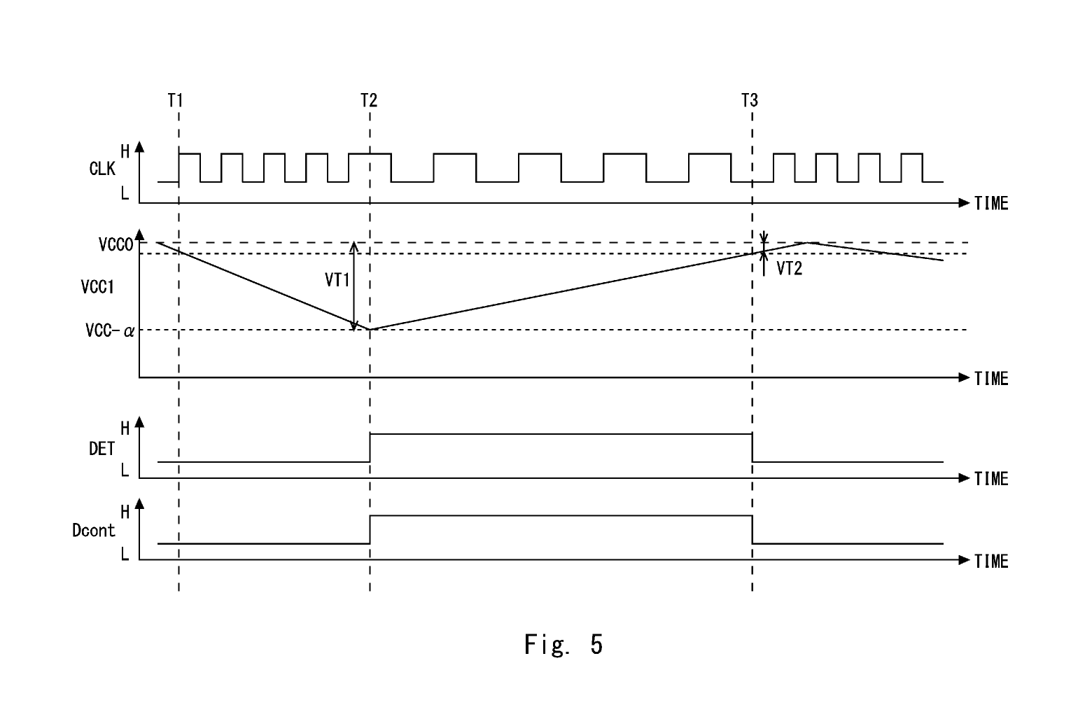

Next, an operation of the semiconductor device 1 according to the first embodiment will be explained. FIG. 5 shows a timing chart for explaining the operation of the semiconductor device 1 according to the first embodiment. As shown in FIG. 5, in the semiconductor device 1 according to the first embodiment, the operations of the charge pump circuits 21 and 22 are started at timing T1. When the charge pump circuits 21 and 22 start the pump operations, the power consumption in these circuits increases, and therefore the monitor voltage VCC1 decreases with time. In the semiconductor device 1 according to the first embodiment, from the timing T1 at which the charge pump circuits 21 and 22 start operating to the period in which the difference between the monitor voltage VCC1 and the determination threshold voltage VCC0 is kept to be smaller than the first threshold voltage VT1, the power supply fluctuation detection signal DET and the delay amount control signal Dcont are kept to the low level (disable state). Accordingly, during this period, the clock generation circuit 12 composes a ring oscillator of three inverters included in the buffer circuit BUF11 and the inverter 39, and the operation clock CLK is generated by this ring oscillator.

When the difference between the monitor voltage VCC1 and the determination threshold voltage VCC0 becomes equal to or larger than the first threshold voltage VT1 at timing T2, the voltage difference detection circuit 11 switches the power supply fluctuation detection signal DET from the low level (disable state) to the high level (enable state). Further, in accordance with this switch of the power supply fluctuation detection signal DET, the delay time switch circuit 13 switches the delay amount control signal Dcont from the low level (disable state) to the high level (enable state). In the semiconductor device 1 according to the first embodiment, in the period from the timing T2 to the timing that the difference between the monitor voltage VCC1 and the determination threshold voltage VCC0 becomes equal to or smaller than the second threshold voltage VT2, the power supply fluctuation detection signal DET and the delay amount control signal Dcont are kept to the high level (enable state). Therefore, during this period, the clock generation circuit 12 composes a ring oscillator of five inverters included in the buffer circuits BUF11 and BUF12 and the inverter 39, and this ring oscillator generates the operation clock CLK. That is, during this period, the frequency of the operation clock CLK becomes lower than that before the timing T2.

In the semiconductor device 1 according to the first embodiment, in the period in which the frequency of the operation clock CLK is reduced, the power consumption of the charge pump circuits 21 and 22 per unit time is reduced, and therefore the monitor voltage VCC1 increases so as to approach the determination threshold voltage VCC0. After that, when the difference between the monitor voltage VCC1 and the determination threshold voltage VCC0 becomes equal to or smaller than the second threshold voltage VT2 at timing T3, the voltage difference detection circuit 11 switches the power supply fluctuation detection signal DET from the high level (enable state) to the low level (disable state). Further, in accordance with the switch of the power supply fluctuation detection signal DET, the delay time switch circuit 13 switches the delay amount control signal Dcont from the high level (enable state) to the low level (disable state). In the semiconductor device 1 according to the first embodiment, in a period from the timing T3 to the timing that the difference between the monitor voltage VCC1 and the determination threshold voltage VCC0 becomes equal to or larger than the first threshold voltage VT1, the power supply fluctuation detection signal DET and the delay amount control signal Dcont are kept to the low level (disable state). Therefore, after timing T3, the clock generation circuit 12 composes a ring oscillator of three inverters included in the buffer circuit BUF11 and the inverter 39, and generates the operation clock CLK by this ring oscillator. That is, during this period, the frequency of the operation clock CLK becomes higher than that before the timing T3.

From the aforementioned description, the semiconductor device 1 according to the first embodiment reduces the frequency of the operation clock CLK that operates the internal circuit 10 in the temporary period from the timing that the difference between the monitor voltage VCC1, which is the voltage of the main power supply line W0 to which the internal circuit 10 is connected, and the determination threshold voltage VCC0, which is the voltage of the main power supply line W0, becomes equal to or larger than the first threshold voltage to the timing that this difference becomes equal to or smaller than the second threshold voltage. That is, the semiconductor device 1 according to the first embodiment reduces the frequency of the operation clock CLK and reduces the amount of the current flowing through the branch power supply line W2 only when the monitor voltage VCC1 is reduced while causing the internal circuit 10 to perform most of the operations therein based on the operation clock CLK having an original frequency, thereby being able to cause the monitor voltage VCC1 to return to the original voltage. Accordingly, the semiconductor device 1 according to the first embodiment is able to operate the internal circuit 10 by the operation clock CLK at the frequency as high as possible while preventing the decrease in the power supply voltage supplied to the internal circuit 10.

### Second Embodiment

In a second embodiment, a semiconductor device 2, which is a modified example of the semiconductor device 1 described in the first embodiment, will be explained. In the description according to the second embodiment, the components the same as those described in the first embodiment are denoted by the symbols the same as those attached to the components in the first embodiment and the descriptions thereof will be omitted.

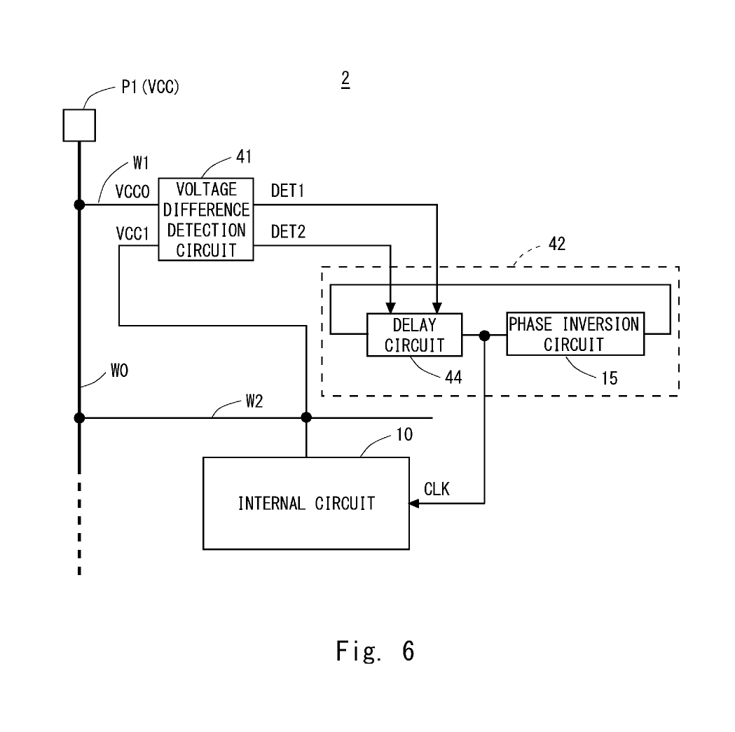

FIG. 6 shows a block diagram of the semiconductor device 2 according to the second embodiment. As shown in FIG. 6, the semiconductor device 2 according to the second embodiment includes a voltage difference detection circuit 41 in place of the voltage difference detection circuit 11 of the semiconductor device 1 according to the first embodiment and includes a clock generation circuit 42 in place of the clock generation circuit 12. Further, in the clock generation circuit 42, the delay time switch circuit 13 included in the clock generation circuit 12 is eliminated, and the delay circuit 14 is replaced by a delay circuit 44.

The voltage difference detection circuit 41 controls each of a first power supply fluctuation detection signal DET1 and a second power supply fluctuation detection signal DET2 in accordance with the voltage level of the monitor voltage VCC1.

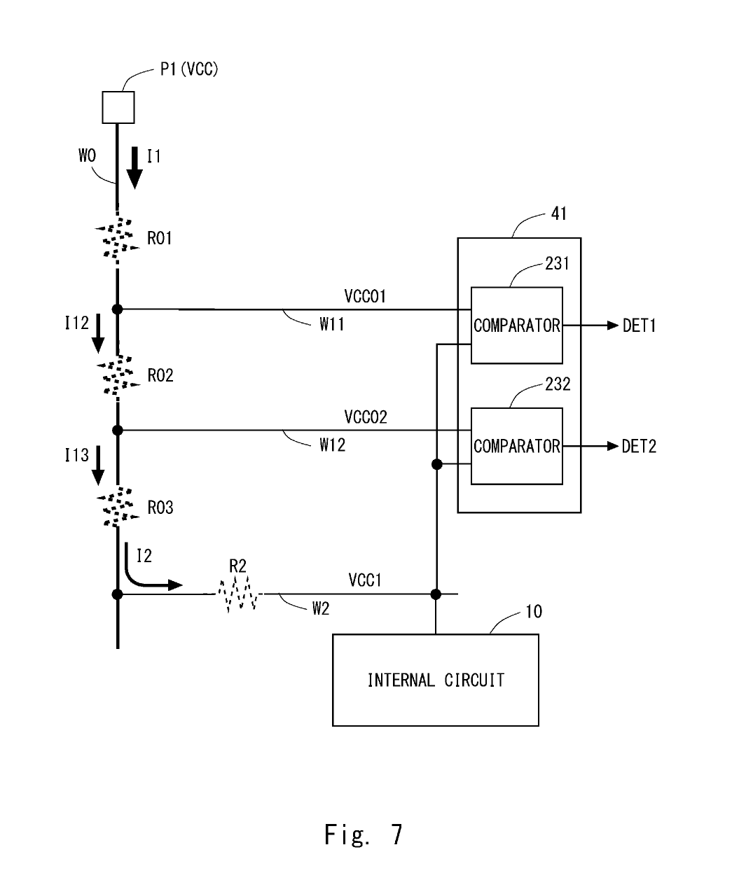

FIG. 7 shows a block diagram of the voltage difference detection circuit 41 according to the second embodiment. As shown in FIG. 7, the voltage difference detection circuit 41 includes a first comparator (a comparator 231) and a second comparator (a comparator 232). The comparator 231 receives a first determination threshold voltage VCC01 acquired from a first measurement point of the main power supply line W0 at which the distance from the branching point at which the branch power supply line W2 is branched off from the main power supply line W0 to the first measurement point becomes a first distance and the monitor voltage VCC1. Then the comparator 231 switches the first power supply fluctuation detection signal DET1 to the enable state when the voltage difference between the first determination threshold voltage VCC01 and the monitor voltage VCC1 becomes equal to or larger than a predetermined third threshold voltage VT3. Further, the comparator 231 switches the first power supply fluctuation detection signal DET1 to the disable state when the voltage difference between the first determination threshold voltage VCC01 and the monitor voltage VCC1 becomes equal to or smaller than a fourth threshold voltage VT4 smaller than the third threshold voltage VT3.

The comparator 232 receives a second determination threshold voltage VCC02 acquired from a second measurement point of the main power supply line W0 at which the distance from the branching point at which the branch power supply line W2 is branched off from the main power supply line W0 to the second measurement point becomes a second distance smaller than the first distance and the monitor voltage VCC1. Then the comparator 232 switches, when the voltage difference between the first determination threshold voltage VCC02 and the monitor voltage VCC1 becomes equal to or larger than a pre-configured fifth threshold voltage VT5, the second power supply fluctuation detection signal DET2 to the enable state. Further, the comparator 232 switches, when the voltage difference between the second determination threshold voltage VCC02 and the monitor voltage VCC1 becomes equal to or smaller than a sixth threshold voltage VT6, which is smaller than the fifth threshold voltage VT5, the second power supply fluctuation detection signal DET2 to the disable state.

Comparing the first determination threshold voltage VCC01 with the second determination threshold voltage VCC02, in the current path formed in the main power supply line W0, the measurement point of the second determination threshold voltage VCC02 is positioned in the downstream of the measurement point of the first determination threshold voltage VCC01. Therefore, the second determination threshold voltage VCC02 becomes lower than the first determination threshold voltage VCC01.

From the aforementioned discussion, when the monitor voltage VCC1 is decreased, the voltage difference detection circuit 41 first switches the first power supply fluctuation detection signal DET1 from the disable state to the enable state, and when the monitor voltage VCC1 is further decreased, the voltage difference detection circuit 41 switches the second power supply fluctuation detection signal DET2 from the disable state to the enable state. On the other hand, in the aspect in which the monitor voltage VCC1 is increased, the voltage difference detection circuit 41 first switches the second power supply fluctuation detection signal DET1 from the enable state to the disable state, and when the monitor voltage VCC1 is further increased, the voltage difference detection circuit 41 switches the first power supply fluctuation detection signal DET1 from the enable state to the disable state.

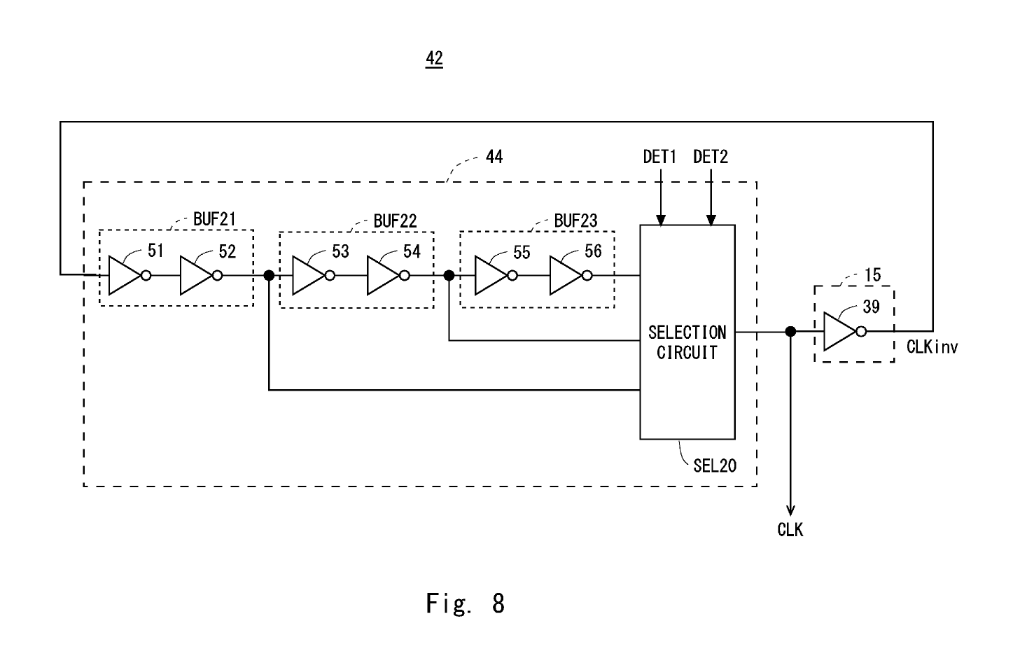

Next, the clock generation circuit 42 will be explained. FIG. 8 shows a block diagram of the clock generation circuit 42 according to the second embodiment. As shown in FIG. 8, the clock generation circuit 42 includes a delay circuit 44 and the phase inversion circuit 15. Further, the clock generation circuit 42 includes buffer circuits BUF21, BUF22, and BUF23, and a selection circuit SEL20.

The buffer circuit BUF21 includes inverters 51 and 52 that are connected in series. The buffer circuit BUF22 includes inverters 53 and 54 that are connected in series. The buffer circuit BUF23 includes inverters 55 and 56 that are connected in series. The buffer circuits BUF21-BUF23 are connected in series. Further, an inversion operation clock CLKinv output from the phase inversion circuit 15 is input to the buffer circuit BUF21. The output signals of the buffer circuits BUF21-BUF23 are input to the selection circuit SEL20. The selection circuit SEL20 selects one of the output signals of the buffer circuits BUF21-BUF23 in accordance with the first power supply fluctuation detection signal DET1 and the second power supply fluctuation detection signal DET2 and outputs the selected signal to the phase inversion circuit 15. Further, the output signal of the selection circuit SEL20 is the operation clock CLK.

That is, in the clock generation circuit 42 according to the second embodiment, one of the output signals of the buffer circuits BUF21-BUF23 is selected based on the first power supply fluctuation detection signal DET1 and the second power supply fluctuation detection signal DET2, whereby the number of inverters that compose the ring oscillator is increased or decreased. Accordingly, the semiconductor device 2 according to the second embodiment changes the frequency of the operation clock CLK to be supplied to the internal circuit 10 in accordance with the voltage level of the monitor voltage VCC1.

From the aforementioned description, in the semiconductor device 2 according to the second embodiment, the frequency of the operation clock CLK can be switched at two stages in accordance with the voltage level of the monitor voltage VCC1. Accordingly, in the semiconductor device 2 according to the second embodiment, it is possible to control the frequency of the operation clock CLK more finely than that in the semiconductor device 1 according to the first embodiment.

### Third Embodiment

In a third embodiment, a semiconductor device 3, which is a modified example of the semiconductor device 1 described in the first embodiment, will be explained. In the description of the third embodiment, the components the same as those described in the first embodiment are denoted by the symbols the same as those attached to the components in the first embodiment and the descriptions thereof will be omitted.

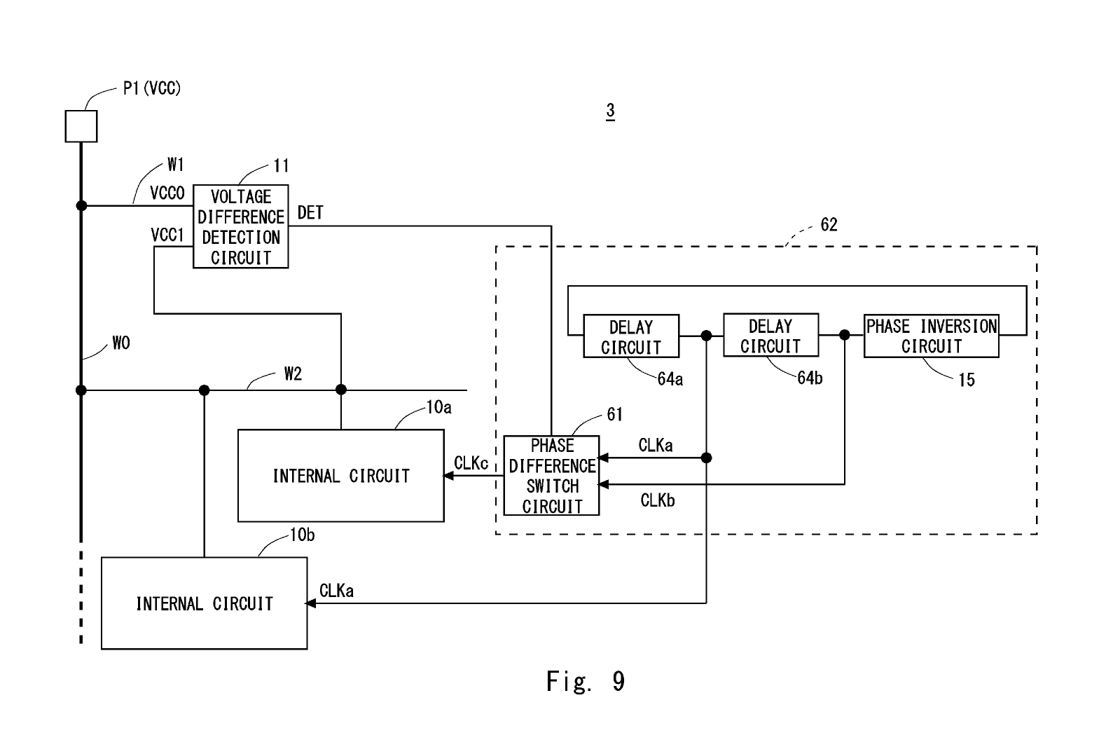

FIG. 9 shows a block diagram of the semiconductor device 3 according to the third embodiment. As shown in FIG. 9, the semiconductor device 3 according to the third embodiment includes a clock generation circuit 62 in place of the clock generation circuit 12 of the semiconductor device 1 of the first embodiment. Further, the semiconductor device 3 according to the third embodiment includes a first internal circuit 10a and a second internal circuit 10b as the internal circuit. The first internal circuit 10a operates based on a second operation clock CLKc output from the clock generation circuit 62 and the second internal circuit 10b operates based on a first operation clock CLKa output from the clock generation circuit 62. In the description of the third embodiment, it is assumed that each of the first internal circuit 10a and the second internal circuit 10b includes the charge pump circuit described with reference to FIG. 2.

The clock generation circuit 62 makes the phase of the first operation clock CLKa different from the phase of the second operation clock CLKc to output the first operation clock CLKa and the second operation clock CLKc in the period in which the power supply fluctuation detection signal DET is in the enable state, and makes the phase of the first operation clock CLKa match the phase of the second operation clock CLKc to output the first operation clock CLKa and the second operation clock CLKc in the period in which the power supply fluctuation detection signal DET is in the disable state.

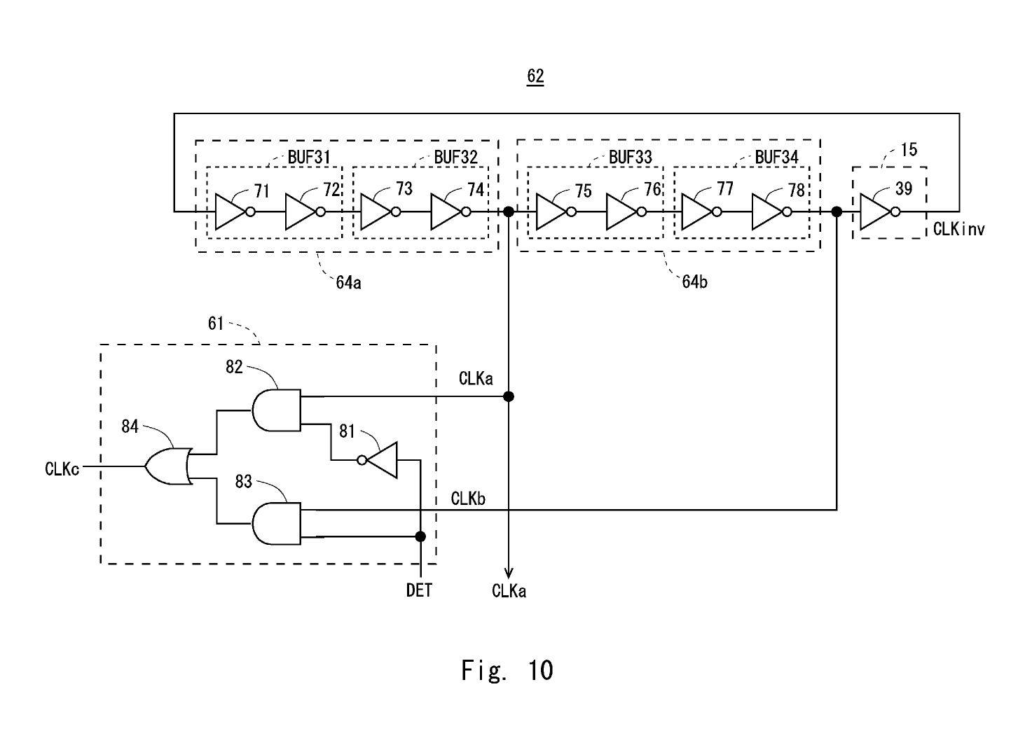

Now, the clock generation circuit 62 will be explained in detail. FIG. 10 shows a block diagram of the clock generation circuit 62 according to the third embodiment. As shown in FIG. 10, the clock generation circuit 62 includes a phase difference switch circuit 61, delay circuits 64a and 64b, and the phase inversion circuit 15.

The clock generation circuit 62 includes the delay circuits 64a and 64b including buffer circuits (e.g., a pair of buffer circuits BUF31 and BUF32 and a pair of buffer circuits BUF33 and BUF34) that are connected in series. Further, each of the buffer circuits includes two inverters that are connected in series. Then the clock generation circuit 62 connects the delay circuits 64a and 64b and the phase inversion circuit 15 in series, thereby forming the ring oscillator. The clock generation circuit 62 outputs the operation clock CLKa from the delay circuit 64a and outputs the operation clock CLKb from the delay circuit 64b. Since the operation clock CLKa and the operation clock CLKb are output from different stages of the ring oscillator, they have phases different from each other. Further, while the clock generation circuit 62 outputs the operation clock CLKa as the first operation clock CLKa, it outputs the operation clock CLKb only via the phase difference switch circuit 61.

The phase difference switch circuit 61 selects one of the operation clock CLKa and the operation clock CLKb based on the power supply fluctuation detection signal DET and outputs the operation clock that has been selected as the second operation clock CLKc. The phase difference switch circuit 61 includes an inverter 81, AND circuits 82 and 83, and an OR circuit 84. The inverter 81 outputs a signal obtained by inverting the power supply fluctuation detection signal DET to the AND circuit 82. The AND circuit 82 transmits the operation clock CLKa to the OR circuit 84 when the power supply fluctuation detection signal DET inverted by the inverter 81 is in the high level, that is, when the power supply fluctuation detection signal DET is in the disable state. The AND circuit 83 transmits the operation clock CLKb to the OR circuit 84 when the power supply fluctuation detection signal DET is in the high level, that is, when the power supply fluctuation detection signal DET is in the enable state. The OR circuit 84 outputs a signal, which is a logical OR of the signal output from the AND circuit 82 and the signal output from the AND circuit 83, as the second operation clock CLKc.

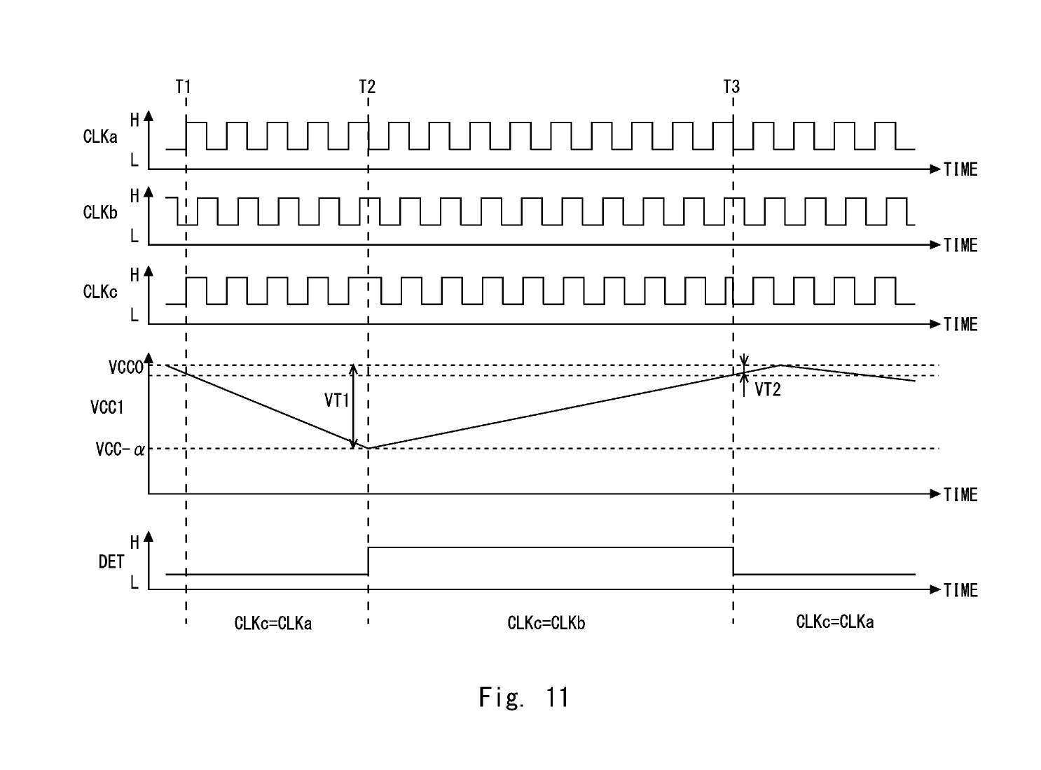

Next, an operation of the semiconductor device 3 according to the third embodiment will be explained. FIG. 11 shows a timing chart for describing the operation of the semiconductor device according to the third embodiment. As shown in FIG. 11, in the semiconductor device 3 according to the third embodiment, the operations of the first internal circuit 10a and the second internal circuit 10b are started at timing T1. When each of the first internal circuit 10a and the second internal circuit 10b starts the pumping operation, the power consumption in these circuits increases, and the monitor voltage VCC1 decreases with time. In the semiconductor device 3 according to the third embodiment, from the timing T1 at which the first internal circuit 10a and the second internal circuit 10b start operating to the period in which the difference between the monitor voltage VCC1 and the determination threshold voltage VCC0 is smaller than the first threshold voltage VT1, the power supply fluctuation detection signal DET is kept to the low level (disable state). During this period, the clock generation circuit 62 selects the operation clock CLKa as the second operation clock CLKc, and the phase of the first operation clock CLKa matches the phase of the second operation clock CLKc.

When the difference between the monitor voltage VCC1 and the determination threshold voltage VCC0 becomes equal to or larger than the first threshold voltage VT1 at timing T2, the voltage difference detection circuit 11 switches the power supply fluctuation detection signal DET from the low level (disable state) to the high level (enable state). In the semiconductor device 3 according to the third embodiment, in the period from the timing T2 to the timing that the difference between the monitor voltage VCC1 and the determination threshold voltage VCC0 becomes equal to or smaller than the second threshold voltage VT2, the power supply fluctuation detection signal DET is kept to the high level (enable state). Accordingly, during this period, the clock generation circuit 62 selects the operation clock CLKb whose phase is different from that of the operation clock CLKa as the second operation clock CLKc. That is, in this period, the phase of the first operation clock CLKa and that of the second operation clock CLKb are different from each other. In another aspect, in this period, the timing of the edge of the operation clock in this period is different from that before the timing T2.

In the semiconductor device 3 according to the third embodiment, in the period in which the phase of the first operation clock CLKa and that of the second operation clock CLKc are different from each other, the peak of the power consumption that is generated due to the edge of the operation clock is reduced and is temporally smoothed. Therefore, the monitor voltage VCC1 is increased to approach the determination threshold voltage VCC0. After that, when the difference between the monitor voltage VCC1 and the determination threshold voltage VCC0 becomes equal to or smaller than the second threshold voltage VT2 at timing T3, the voltage difference detection circuit 11 switches the power supply fluctuation detection signal DET from the high level (enable state) to the low level (disable state). In the semiconductor device 3 according to the third embodiment, in the period from the timing T3 to the timing that the difference between the monitor voltage VCC1 and the determination threshold voltage VCC0 becomes equal to or larger than the first threshold voltage VT1, the power supply fluctuation detection signal DET is kept to the low level (disable state). Therefore, after timing T3, the clock generation circuit 62 outputs the operation clock CLKa as the second operation clock CLKc.

From the aforementioned description, in the semiconductor device 3 according to the third embodiment, when the monitor voltage VCC1 is reduced, the phases of the operation clocks supplied to the plurality of internal circuits connected to the branch power supply line W2 are shifted from each other. Accordingly, the timing of the peak of the current that flows through the branch power supply line W2 is distributed in the direction of the time axis, and the magnitude of the current peak is decreased. Accordingly, in the semiconductor device 3 according to the third embodiment, the decrease in the voltage of the branch power supply line W2 is suppressed, in a way similar to that in the semiconductor device 1 according to the first embodiment.

While the disclosure has been described in terms of several embodiments, those skilled in the art will recognize that the disclosure can be practiced with various modifications within the spirit and scope of the appended claims and the disclosure is not limited to the examples described above.

Further, the scope of the claims is not limited by the embodiments described above.

Furthermore, it is noted that, Applicant's intent is to encompass equivalents of all claim elements, even if amended later during prosecution.

The first and third embodiments can be combined as desirable by one of ordinary skill in the art.

What is claimed is:

1. A semiconductor device comprising:
a first power supply line;
a second power supply line that is branched off from a branching point on the first power supply line;
a power supply fluctuation detection circuit configured to output a power supply fluctuation detection signal, the power supply fluctuation detection signal being switched to an enable state when a voltage difference between a determination threshold voltage acquired from a position on the first power supply line that is closer to a power supply source than the branching point is and a monitor voltage acquired from the second power supply line becomes equal to or larger than a pre-configured first threshold voltage and switched to a disable state when the voltage difference between the determination threshold voltage and the monitor voltage becomes equal to or smaller than a second threshold voltage smaller than the first threshold voltage;
an internal circuit configured to receive power from the second power supply line; and
a clock generation circuit configured to supply an operation clock to the internal circuit,
in which the clock generation circuit makes a timing of a rising edge or a falling edge of the operation clock in a period in which the power supply fluctuation detection signal is in the enable state different from a timing of a rising edge or a falling edge of the operation clock in a period in which the power supply fluctuation detection signal is in the disable state.

2. The semiconductor device according to claim 1, wherein the power supply fluctuation detection circuit acquires the monitor voltage from a point near a connection point of the second power supply line to which the internal circuit is connected.

3. The semiconductor device according to claim 1, wherein
the clock generation circuit comprises an oscillation circuit, the oscillation circuit comprising odd-numbered inverters connected in series in a loop manner and outputting an output of any one of the plurality of inverters as the operation clock, and
when the power supply fluctuation detection signal is in the enable state, the circuit configuration is switched in such a way that the number of inverters that compose the oscillation circuit becomes larger than that when the power supply fluctuation detection signal is in the disable state.

4. The semiconductor device according to claim 1, wherein
the power supply fluctuation detection circuit comprises:
a first comparator configured to output a first power supply fluctuation detection signal, the first power supply fluctuation detection signal being switched to an enable state when a voltage difference between a first determination threshold voltage acquired from a first measurement point of the first power supply line, the distance from the first measurement point to the branching point being a first distance, and the monitor voltage becomes equal to or larger than a pre-configured third threshold voltage and switched to a disable state when the voltage difference between the first determination threshold voltage and the monitor voltage becomes equal to or smaller than a fourth threshold voltage smaller than the third threshold voltage; and
a second comparator configured to output a second power supply fluctuation detection signal, the second power supply fluctuation detection signal being switched to an enable state when a voltage difference between a second determination threshold voltage acquired from a second measurement point of the first power supply line, the distance from the second measurement point to the branching point being a second distance smaller than the first distance, and the monitor voltage becomes equal to or larger than a pre-configured fifth threshold voltage and switched to a disable state when the voltage difference between the second determination threshold voltage and the monitor voltage becomes equal to or smaller than a sixth threshold voltage smaller than the fifth threshold voltage,
the clock generation circuit comprises:
a phase inversion circuit configured to switch a logic level of a first output signal in such a way that the logic level of the first output signal becomes opposite to the logic level of an input signal;
a first buffer circuit configured to switch a logic level of a second output signal in such a way that the logic level of the second output signal matches the logic level of the first output signal;
a second buffer circuit configured to switch a logic level of a third output signal in such a way that the logic level of the third output signal matches the logic level of the second output signal;
a third buffer circuit configured to switch a logic level of a fourth output signal in such a way that the logic level of the fourth output signal matches the logic level of the third output signal; and
a selection circuit configured to select any one of the second to fourth output signals in accordance with the first power supply fluctuation detection signal and the second power supply fluctuation detection signal and use the selected output signal as a signal input to the phase inversion circuit.

5. The semiconductor device according to claim 1, wherein the clock generation circuit makes a frequency of the operation clock in a period in which the power supply fluctuation detection signal is in the enable state lower than the frequency of the operation clock in a period in which the power supply fluctuation detection signal is in the disable state.

6. The semiconductor device according to claim 1, wherein
the internal circuit comprises a first internal circuit and a second internal circuit that operate in operation clocks different from each other,
the clock generation circuit outputs a first operation clock to be supplied to the first internal circuit and a second operation clock to be supplied to the second internal circuit, and
the clock generation circuit makes the phase of the first operation clock different from the phase of the second operation clock to output the first operation clock and the second operation clock in a period in which the power supply fluctuation detection signal is in the enable state, and makes the phase of the first operation clock match the phase of the second operation clock to output the first operation clock and the second operation clock in a period in which the power supply fluctuation detection signal is in the disable state.
